(19) United States
(12) Patent Application Publication
(10) Pub. No.: US 2007/0096113 A1
(43) Pub. Date: May 3, 2007

(54) Led device

(75) Inventors: Kyoji Inoshita, Hirakata (JP); Seiichi Tokunaga, Suita (JP); Shingo Kameyama, Ibaraki (JP)

Correspondence Address: NDQ&M WATCHSTONE LLP, 1300 EYE STREET, NW, SUITE 1000 WEST TOWER, WASHINGTON, DC, 20005, US

(73) Assignee: Sanyo Electric Co., Ltd., Moriguchi (JP)

(21) Appl. No.: 11/524,257

(22) Filed: Sep. 21, 2006

(30) Foreign Application Priority Data
Sep. 21, 2005 (JP) JP2005-273655
Sep. 20, 2006 (JP) JP2005-254857

(51) Int. Cl. H01L 33/00; H01L 31/12; H01L 27/15; H01L 29/26

(52) U.S. Cl. 257/79

(57) ABSTRACT

An LED device includes; an LED chip, a first layer provided on the LED chip, a second layer provided on the first layer, and a third layer provided on the second layer. The first layer has a refractive index n1. The second layer has a refractive index n2, and includes phosphors emitting fluorescence light by absorption of excitation light emitted from the LED chip. The third layer has a refractive index n3. The refractive index n2 is larger than the refractive index n3.

### CROSS REFERENCE TO RELATED APPLICATIONS

This application is based upon and claims the benefit of priority from prior Japanese Patent Application No. 2005-273655, filed on Sep. 21, 2005; and prior Japanese Patent Application No. 2006-254857, filed on Sep. 20, 2006; the entire contents of which are incorporated herein by reference.

### BACKGROUND OF THE INVENTION

1. Field of the Invention

The present invention relates to an LED device including LED chip and phosphors emitting fluorescence light by absorption of excitation light.

2. Description of the Related Art

A white LED device includes a light emitting diode (LED) chip implemented on a base and a transparent resin containing phosphors covering the LED chip is known. LED devices have functions and effects such as compactness, low power consumption, and a long life. The white LED device has already been put into practical use as a replacement of the existing small lamp such as a miniature bulb and a small night light. It is also expected that the white LED device can also be a light source for general lighting in place of an incandescent lamp and a fluorescent lamp owing to an upcoming efficiency increase and an upcoming cost reduction.

As shown in FIG. 1, a general white LED device 100 of a bullet type has the following structure. First, an LED chip 111 emitting ultraviolet or blue light is mounted and fixed on a recessed portion formed by a bowl-shaped first lead frame 112. Transparent resin 114 containing phosphors (hereinafter, referred to as phosphors-containing resin), which is obtained by mixing phosphors 113, is filled into the recessed portion formed by the first lead frame 112 to cover the LED chip 111. A periphery of the first lead frame 112 as well as a second lead frame 115, which is disposed close to face the first lead frame 112, is covered with third resin 116, thus forming a predetermined shape.

A light emitting principle of visible light by the LED device with the structure as described above is as follows. The phosphors-containing resin 114 is irradiated with the ultraviolet light emitted from the LED chip 111. This excites the phosphors 113 to emit the visible light. The emitted visible light is extracted to the outside through the third resin 116. At this time, the phosphors-containing resin 114 receives the excitation light from the inside, and emits fluorescence light to the outside.

Also, an LED device for improving extraction efficiency of light emitted from the LED device and directivity of the light emitted from the LED device, is suggested. For example, as described in Japanese Unexamined Patent Publication No. 2004-265985 and Japanese Unexamined Patent Publication No. 2005-123588, the LED devices having a structure in which a low refractive index resin covers an LED chip, and a high refractive index resin covers the low refractive index resin, are suggested.

### SUMMARY OF THE INVENTION

An aspect of an LED device includes; an LED chip, a first layer provided on the LED chip, a second layer provided on the first layer, and a third layer provided on the second layer. The first layer has a refractive index n1. The second layer has a refractive index n2, and includes phosphors emitting fluorescence light by absorption of excitation light emitted from the LED chip. The third layer has a refractive index n3. The refractive index n2 is larger than the refractive index n3.

Note that, when the particle diameter of the phosphors is equal to or larger than the wavelength of the light, the refractive index n2 of the second layer can be regarded as the refractive index of transparent resin forming the second layer. On the contrary, when the particle diameter of the phosphors is sufficiently smaller than the wavelength of the light, the refractive index n2 of the second layer can be regarded as effective refractive index upon consideration of the phosphors.

In an aspect of the LED device according to the above aspect, the refractive index n2 is larger than the refractive index n1.

In an aspect of the LED device according to the above aspect, the refractive index n1 is equal to the refractive index n2.

In an aspect of the LED device according to the above aspect, the refractive index n1 is larger than the refractive index n2.

In an aspect of the LED device according to the above aspect, the refractive index n3 is larger than the refractive index n1.

In an aspect of the LED device according to the above aspect, the LED chip emits an ultraviolet light as the excitation light. The phosphors emit a visible light as the fluorescence light.

In an aspect of the LED device according to the above aspect, the second layer is composed of a phosphor sheet.

In an aspect of the LED device according to the above aspect, The LED chip has a light emitting surface which emits the excitation light. The light emitting surface includes an uneven surface having small-scaled convex portion or concave portion.

In an aspect of the LED device according to the above aspect, the first layer and second layer are formed of resins.

In an aspect of the LED device according to the above aspect, the third layer is formed of a resin.

In an aspect of the LED device according to the above aspect, the third layer is formed of a glass.

### BRIEF DESCRIPTION OF THE DRAWINGS

FIG. 1 shows a cross-sectional view of an LED device of a conventional example.

FIG. 2 shows a cross-sectional view of an LED device of a first embodiment of the present invention.

FIG. 3 shows an explanatory view showing behaviors of ultraviolet light UV and visible light VL in a second resin layer in the first embodiment.

FIG. 4 shows a cross-sectional view of an LED device of a second embodiment of the present invention.

FIG. 5 shows a cross-sectional view of an LED device of a third embodiment of the present invention.

FIG. 6 shows a cross-sectional view of an LED device of a fourth embodiment of the present invention.

FIG. 7 shows Table 1 of refractive indices of respective resins in devices of examples of the present invention and a device of Comparative example.

FIG. 8 shows Table 2 of measurement results of light emission characteristics in the devices of the examples of the present invention and the device of Comparative example.

FIG. 9 shows a plan view, front view, side view, and center cross-sectional view of lead frames used in the examples of the present invention.

FIG. 10 shows a cross-sectional view of a peripheral portion of an LED chip in an LED device used in the examples of the present invention.

FIG. 11 shows a cross-sectional view of the LED device used in the examples of the present invention.

FIG. 12 shows a cross-sectional view of the LED device of a fifth embodiment of the present invention.

FIG. 13 shows a cross-sectional view of the LED device of a sixth embodiment of the present invention.

FIG. 14 shows Table 3 of refraction indices and measurement results according to devices in examples of the present invention and devices in Comparative example.

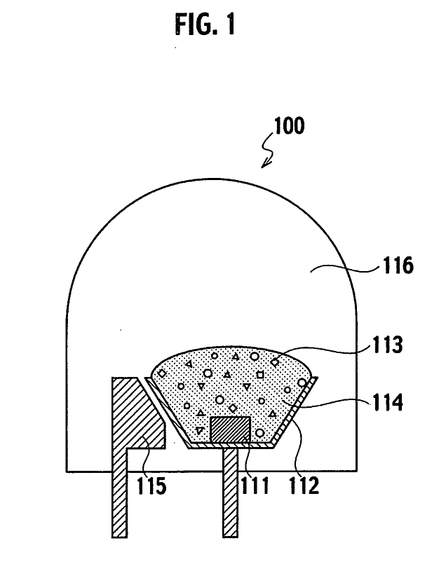

### DETAILED DESCRIPTION OF THE PREFERRED EMBODIMENTS

A description will be made below in detail of embodiments of the present invention based on the drawings.

### FIRST EMBODIMENT

Configuration of LED Device

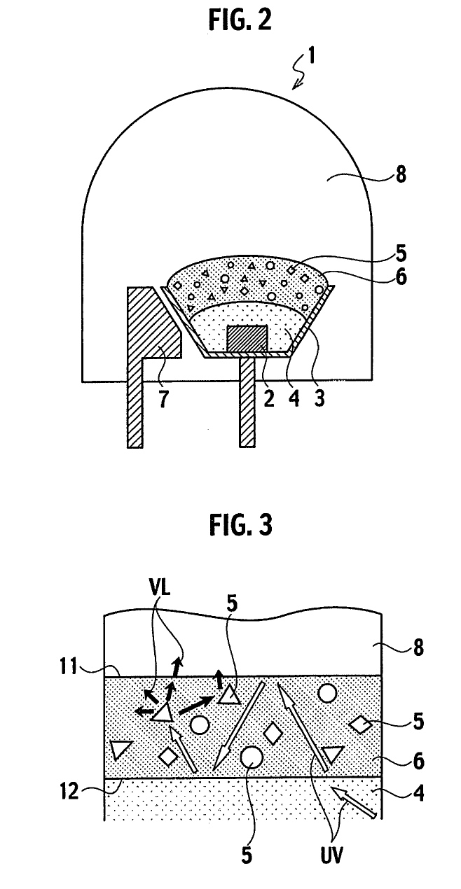

FIG. 2 shows an LED device 1 of a first embodiment of the present invention. The LED device 1 is a white LED device of a bullet type. The LED device 1 has the following structure. First, an LED chip 2 emitting ultraviolet light is mounted and fixed on a recessed portion formed by a bowl-shaped first lead frame 3. Then, transparent resin having a refractive index n1 is filled in the recessed portion formed by the first lead frame 3, and then, is hardened. Thus, a first resin layer 4 is formed to cover the LED chip 2. Thereafter, transparent resin (hereinafter, referred to as phosphors-containing resin), which has a refractive index n2 and which is obtained by mixing phosphors 5, is filled, on the first resin layer 4, in the recessed portion formed by the first lead frame 3, and then, is hardened. Thus, a second resin layer 6 is formed to cover the first resin layer 4. Moreover, a periphery of the first lead frame 3 as well as a second lead frame 7, which is disposed close to face the first lead frame 3, is covered with a third resin layer 8 having a refractive index n3. In this way, the structure of the LED device 1 is formed in a predetermined shape. Here, relationships of: n2>n1; and n2>n3 are given among the refractive index n1 of the first resin layer 4, the refractive index n2 of the second resin layer 6, and the refractive index n3 of the third resin layer 8. Note that the LED chip 2 may be any one of a blue light emission type and the ultraviolet light emission type, however, a description will be made of this embodiment on the assumption that the LED chip 2 is of the ultraviolet light emission type.

Manufacturing Method of LED Device

Next, a description will be made of a manufacturing method of the white LED device 1 with the above-described structure. For shapes of the ultraviolet LED chip 2, the first lead frame 3, the second lead frame 7, and the third resin layer 8, those in a general white LED device are used. Moreover, for the LED chip 2, the one having an uneven structure formed on a surface can also be used in order to enhance light extraction efficiency to the outside. The uneven structure of the surface enhances a light extraction effect more significantly, as a difference in refractive index between the chip and a periphery thereof becomes larger. Accordingly, the uneven structure of the surface is suitable for the structure of the present invention, which uses the low refractive index of resin covering the chip.

First, the LED chip 2 is mounted on the recessed portion formed by the first lead frame 3, and is connected to the second lead frame 7 by wire bonding. Next, as the resin of the first resin layer 4, for example, silicon resin with the refractive index n1 (=1.42) is injected into the recessed portion formed by the lead frame 3 to an extent where the LED chip 2 is embedded. Then, the resin is hardened by heating, and the first resin layer 4 is thus formed.

Thereafter, as the phosphors-containing resin of the second resin layer 6, for example, the one formed by mixing in advance, silicon resin with the refractive index n2 (=1.56) and plural types of general phosphors 5 each emitting light, by ultraviolet excitation, in a wavelength range of visible light is injected into the recessed portion formed by the lead frame 3. Then, the resin is hardened by heating.

The phosphors 5 easily absorb the ultraviolet light, while the phosphors 5 hardly absorb the visible light. Moreover, it is preferable that the refractive index of the phosphors 5 be equal to or higher than that of the resin of the second resin layer 6. This is for suppressing the effective refractive index n2 of the second resin layer 6 including the phosphors 5 from being lower than the refractive indices n1 and n3 respectively of the first resin layer 4 and the third resin layer 8.

After the second resin layer 6 is formed, in order to form the third resin layer 8, for example, LED portions of the lead frames 3 and 7 are inserted into the one prepared by filling the silicon resin with the refractive index of 1.52 into a mold. Then, the silicon resin is hardened by heating. In this way, the third resin layer 8 is integrated with the first lead frame 3 and the second lead frame 7 so as to cover these frames concerned, and the LED device 1 is thus formed. Thereafter, the LED device 1 thus formed is taken out from the mold, and the white LED device 1 of the bullet type is thus obtained.

Note that, since the phosphors 5 are diffusion, refraction and reflection factors of the visible light, which will be described later, it is desirable that a particle diameter of the phosphors 5 be equal to or larger than the wavelength of the light. Moreover, it is preferable that the second resin layer 6 has an uneven thickness. When the thickness of the second resin layer 6 is uneven, a the ultraviolet light incident from the first resin layer 4 is more likely to reach a boundary surface 11 between the third resin layer 8 and the second resin layer 6 at an angle equal to or less than that of total reflection. Moreover, a phosphor sheet which meets the above-described conditions and which has the refractive index n2 larger than the refractive index n1 of the first resin layer 4 can be used for the second resin layer 6 in place of the phosphors-containing resin.

Functions and Effects

The LED device 1 of this embodiment exerts the following functions and effects. In the LED device having uniform refractive index in respective resin layers (the first resin layer 4, the second resin layer 6, and the third resin layer 8), the ultraviolet light for the excitation passes through the fluorescent layer only once, and moreover, the light emitted from the phosphors is radiated to the inside of the LED chip side and to the outside thereof at the same probability.

On the contrary, according to the LED device 1 of this embodiment, the refractive index n2 of the second resin layer 6 is larger than the refractive index n3 of the third resin layer 8. Accordingly, the excitation light UV radiated from the second resin layer 6 to the third resin layer 8 side easily totally reflected on the boundary surface 11. For example, in this embodiment, since the total reflection angle of the boundary surface 11 is 76.9°, the boundary surface 11 reflects the excitation light UV of 76.9° or more among the excitation light UV radiated from the second resin layer 6 to the third resin layer 8 side.

In the LED device 1 according to this embodiment, the refraction index n2 of the second resin layer 6 is larger than the refraction index n1 of the first resin layer 4. Accordingly, the excitation light UV returned from the second resin layer 6 to the first resin layer 4 is easily totally reflected on the boundary surface 12. That is, since the excitation light UV again returns to the second resin layer 6 side, the efficiency of the excitation of the phosphors 5 is improved, and the brightness of the LED device 1 is improved. For example, in this embodiment, since the total reflection angle of the boundary surface 12 is 65.9°, the boundary surface 12 reflects the excitation light UV of 65.9° or more among the excitation light UV returned from the second resin layer 6 to the first resin layer 4 side.

In the LED device 1 according to this embodiment, the refraction index n3 of the third resin layer 8 is larger than the refraction index n1 of the first resin layer 4. Accordingly, a probability of the total reflection of the visible light VL on the boundary surface 11 is higher than a probability of the total reflection of the visible light VL on the boundary surface 12. That is, the decrease in the efficiency of the extraction of the visible light VL can be suppressed, and the brightness of the LED device is improved.

Note that, refraction index n1 of the first resin layer 4, refraction index n2 of the second resin layer 6, and refraction index n3 of the third resin layer 8 are respectively changeable. For example, when silicon resin with a refractive index of 1.62 is used for the second resin layer 6, the total reflection angle on the boundary surface 11 between the second resin layer 6 and the third resin layer 8 becomes 69.8°, and the total reflection angle on the boundary surface 12 between the second resin layer 6 and the first resin layer 4 becomes 61.2°. Thus, the effect of confining the ultraviolet light to the second resin layer 6 is improved, and the excitation efficiency is further improved.

### SECOND EMBODIMENT

Configuration of LED Device

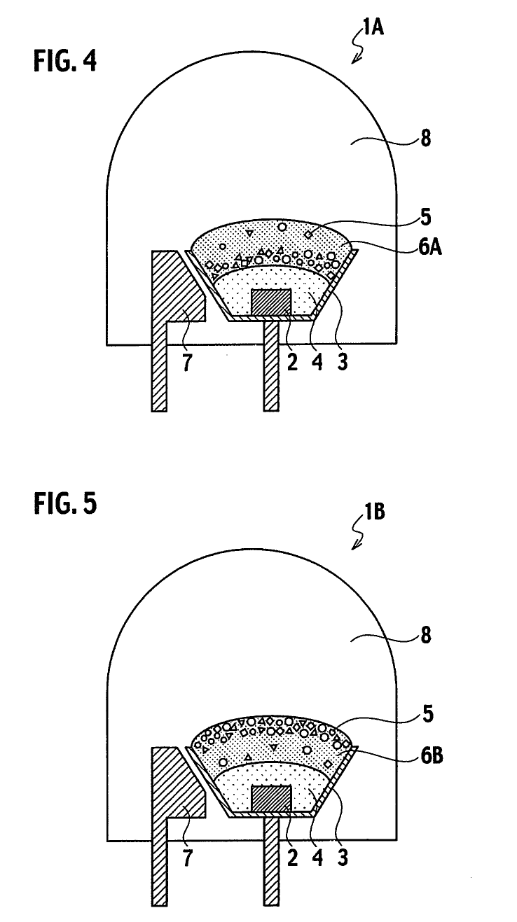

A description will be made of an LED device 1A of a second embodiment of the present invention with reference to FIG. 4. The LED device 1A of this embodiment has a feature in a second resin layer 6A formed by curing the phosphors-containing resin. Specifically, in this embodiment, in the second resin layer 6A, a distribution of the phosphors 5 in the phosphors-containing resin is made uneven. That is, a distributed concentration of the phosphors 5 on the boundary side between the first resin layer 4 and the second resin layer 6A is increased, while a distributed concentration thereof on the boundary side between the second resin layer 6A and the third resin layer 8 is reduced. Note that, since the other constituents are common to those of the first embodiment shown in FIG. 2, a description will be made thereof by using common reference numerals.

Manufacturing Method of LED Device

A description will be made of a manufacturing method of the LED device 1A of the second embodiment, which is constructed as described above. An LED chip 2, a first lead frame 3, a second lead frame 7, a mold shape, refractive indices n1, n2 and n3 respectively of the first resin layer 4, the second resin layer 6A, and the third resin layer 8, and a structure of the LED device 1A are the same as those of the first embodiment. When forming the second resin layer 6A, the phosphors 5 mixed therein are concentrated on the lower side of the second resin layer 6A, that is, at the first resin layer 4 side thereof, for example, by using sedimentation, a difference in specific gravity and the like. Thus, a difference in distribution of the phosphors 5 is made so that the concentration thereof can be larger on the lower side in the second resin layer 6A.

Functions and Effects

According to this embodiment, in addition to the functions and effects of the first embodiment, the LED device 1A has the functions and effects described below. Specifically, the concentration of the phosphors 5 included in the first resin layer 4 side of the second resin layer 6A is higher than the concentration of the phosphors 5 included in the third resin layer 8 side of the second resin layer 6A. In the first resin layer 4 side of the second resin layer 6A, since the concentration of the phosphors 5, which interferes returning of the visible light VL toward the first resin layer 4, is high, the efficiency of the extraction of the visible light VL is hardly decreased. On the contrary, in the third resin layer 8 side of the second resin layer 6A, since the concentration of the phosphors 5, which interferes the extraction of the visible light VL, is low, the efficiency of the extraction of the visible light VL is hardly decreased. That is, the decrease of the efficiency of the extraction of the visible light VL is suppressed and the brightness of the LED device is improved.

Note that, if phosphors having a refractive index larger than that of the phosphors-containing resin itself are employed, the effective refractive index n2 of the second resin layer 6A is increased upon consideration of the phosphors 5 included in he second resin layer 6A. Accordingly, the difference in refractive index between the first resin layer 4 and the second resin layer 6A can be further increased. Thus, the irradiation of the visible light to the inside of the lamp, which becomes a loss, can be further suppressed, and further brightness improvement of the white LED device can be realized.

### THIRD EMBODIMENT

Configuration of LED Device

A description will be made of an LED device 1B of a third embodiment of the present invention with reference to FIG. 5. The LED device 1B of this embodiment has a feature in a second resin layer 6B formed by curing the phosphors-containing resin. Specifically, in this embodiment, in the second resin layer 6B, the distribution of the phosphors 5 in the phosphors-containing resin is made uneven. By contrast to the second embodiment, the distributed concentration of the phosphors 5 on the boundary side between the first resin layer 4 and the second resin layer 6B is reduced, while the distributed concentration thereof on the boundary side between the second resin layer 6B and the third resin layer 8 is increased. Note that, since the other constituents are common to those of the first embodiment shown in FIG. 2, a description will be made thereof by using common reference numerals.

Manufacturing Method of LED Device

A description will be made of a manufacturing method of the LED device 1B of the third embodiment, which is constructed as described above. An LED chip 2, a first lead frame 3, a second lead frame 7, a mold shape, refractive indices n1, n2 and n3 respectively of the first resin layer 4, the second resin layer 6B, and the third resin layer 8, and a structure of the LED device 1B are the same as those of the first embodiment. On the contrary, the second resin layer 6B is formed as described below. Specifically, the resin layer having different concentration of the phosphors is sequentially formed on the first resin layer 4 while the concentration of the phosphors is increased. Thereby, the second resin layer 6B is formed so that the concentration of the phosphors 5 included in the third resin layer 8 side of the second resin layer 6B is higher than the concentration of the phosphors 5 included in the first resin layer 4 side of the second resin layer 6B.

Functions and Effects

In the LED device 1B of this embodiment, in addition to the functions and effects of the first embodiment, the LED device 1B has the functions and effects described below. Specifically, the concentration of the phosphors 5 included in the third resin layer 8 side of the second resin layer 6B is higher than the concentration of the phosphors 5 included in the first resin layer 4 side of the second resin layer 6B. Therefore, in the third resin layer 8 side of the second resin layer 6B, since the concentration of the phosphors 5, which interferes the excitation light UV passing through the third resin layer 8 side by absorption of the excitation light UV, is high, the excitation light UV is efficiently used. On the contrary, since the phosphors 5 included in the third resin layer 8 side of the second resin layer 6B merely interferes the visible light VL radiated by the phosphors included in the third resin layer 8 side of the second resin layer 6B, the visible light VL is easily extracted toward the third resin layer 8 side. That is, the brightness of the LED device 1B is improved.

Note that, if phosphors having a refractive index smaller than the refractive index n2 of the phosphors-containing resin itself of the second resin layer 6B are mixed therein, the difference in refractive index of the visible light can be reduced on the boundary side between the second resin layer 6B and the third resin layer 8. This facilitates to extract the visible light to the outside, and the further brightness improvement of the white LED device can be realized.

### FOURTH EMBODIMENT

Configuration of LED Device

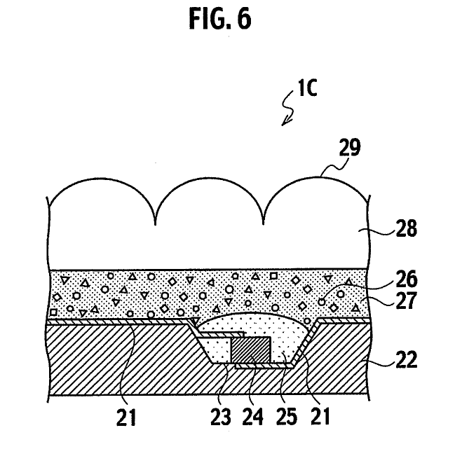

As a fourth embodiment of the present invention, by using FIG. 6, a description will be made of a chip-type white LED device 1C, which uses an LED chip 24 emitting the ultraviolet light. In the chip-type LED device 1C of this embodiment, the LED chip 24 is mounted and fixed on a recessed portion 23 formed by an insulating substrate 22 on which metal lead wires 21 are arranged, and the LED chip 24 is connected to the metal lead wires 21 so as to be capable of being energized. A first resin layer 25 made of the silicon resin, for example, with the refractive index n1=1.42 is filled in the recessed portion 23 and is hardened, so as to cover the LED chip 24. Moreover, a second resin layer 27 made of phosphors-containing resin is formed so as to cover the entire surface of the insulating substrate 22. In this case, the phosphors-containing resin is formed by mixing, in advance, the silicon resin, for example, with the refractive index n2=1.56, and plural types of phosphors 26 each emitting the light in the wavelength range of the visible light by the ultraviolet excitation. Furthermore, a third resin layer 28 made by curing the silicon resin, for example, with the refractive index n3=1.52 is formed so as to cover the second resin layer 27.

Note that a surface 29 of the third resin layer 28 does not have to be a smooth surface. The surface 29 may have a lens array shape as shown in FIG. 6 or an uneven structure, or may have a shape to enhance the light extraction efficiency by forming thereon a fine uneven structure such as a diffraction grating and photonic crystals and so on. Moreover, a glass plate with a refractive index of approximately 1.5 may be adhered to the second resin layer 27 in place of the third resin layer 28. As is the case with the third resin layer 28, a surface of the glass plate may be processed into the shape of the lens array, of the uneven structure, of the fine uneven structure such as the diffraction grating and the photonic crystals or the like.

Manufacturing Method of LED Device

Next, a description will be made of a manufacturing method of the chip-type LED device 1C, which is constructed as described above. First, the recessed portion 23 which is a hole or a groove to an extent where the LED chip 24 is embedded therein is formed on the insulating substrate 22 such as a metal substrate insulated by an oxide film, a resin substrate, a glass substrate, and an Si substrate insulated by SiO₂. Subsequently, the metal lead wires 21 are arranged thereon. Thereafter, the LED chip 24 is mounted and fixed on the recessed portion 23, and is connected to the lead wires 21 so as to be capable of being energized.

Next, in order to form the first resin layer 25, the silicon resin, for example, with the refractive index n1=1.42 is injected into the recessed portion 23 to an extent where the LED chip 24 is embedded. Then, the silicon resin is hardened by heating, and the first resin layer 25 is thus formed. The phosphors-containing resin is made in advance by mixing the silicon resin, for example, with the refractive index n2=1.56 and the plural types of phosphors 26 each emitting the light in the wavelength range of the visible light by the ultraviolet excitation. Thereafter, in order to form the second resin layer 27, the phosphors-containing resin is applied or dropped to cover at least a range to which the ultraviolet light from the LED chip 24 is irradiated, and then, is hardened by heating. Thus, the second resin layer 27 is formed. In this case, besides the structure in which the phosphors 26 contained in the second resin layer 27 are evenly distributed, either of the following structures can be adopted, which are: a structure in which the phosphors are distributed more in the lower portion as shown in the second embodiment; and a structure in which the phosphors are distributed more in the upper portion as shown in the third embodiment.

Note that, since the first resin layer 24 has convex shape, the second resin layer 25 formed on the first resin layer 24 has unequal thickness. Thereby, the ultraviolet light from the LED chip 24 becomes less likely to reach the boundary surface at the angle equal to or less than that of the total reflection. Accordingly, this can strengthen the effect of confining the ultraviolet light to the second resin layer 27. Moreover, in place of the second resin layer 27, a phosphor sheet which meets the above-described conditions and which has the refractive index n2 larger than the refractive index n1 of the first resin layer 25 can be used.

Next, in order to form the third resin layer 28, the silicon resin, for example, with the refractive index n3=1.52 is applied or dropped to cover at least the second resin layer 27. Thereafter, the silicon resin is hardened by heating to form the third resin layer 28. The third resin layer 28 can also be formed by injection molding by using the same resin as described above. Moreover, it is not necessary that the surface 29 of the third resin layer 28 have a flat plate shape, and that the surface 29 can be formed to have the lens array shape, the uneven structure, or the shape capable of enhancing the light extraction efficiency by forming thereon the fine uneven structure such as the diffraction grating and the photonic crystals and so on.

Functions and Effects

The chip-type LED device 1C of this embodiment can exert similar functions and effects to those of the first to third embodiments. In the LED device 1C, the extraction of the visible light to the outside is facilitated, and thereby, realizing the improvement of the brightness. Moreover, the irradiation of the ultraviolet light to the lower side is reduced, and a deterioration of the LED chip 24 can be suppressed. Furthermore, the irradiation of the visible light to the lower side is also reduced, and an extracted amount thereof to the outside is increased, thus making it possible to achieve further improvement of the brightness.

In the chip type LED device 1C, since the first resin layer 25 is filled into the recessed portion 23 formed on the insulating substrate 22, it is easy to form a plurality of the LED chips on the insulating substrate 22. That is, the LED chips can be easily integrated.

Note that, in the above-described first to fourth embodiments, when refraction indices of the resin, the phosphor sheet, or the glass plate denote n1, n2 and n3 respectively from the inside, as long as the refraction indices have the relationships of n2>n3 and n2>n1, it is possible to change each of the above-mentioned resin, florescent sheet, or glass plate to another one. Moreover, in the case of using those whose refraction indices have the relationship of n2>n3>n1, the visible light is more likely to be extracted to the outside, and accordingly, this is more preferable.

### EXAMPLE 1

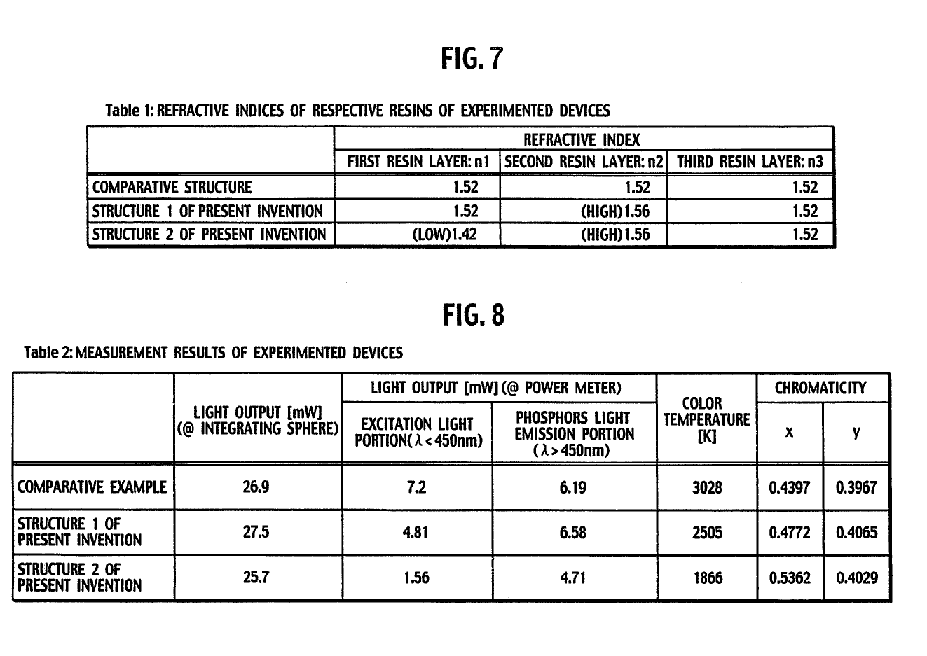

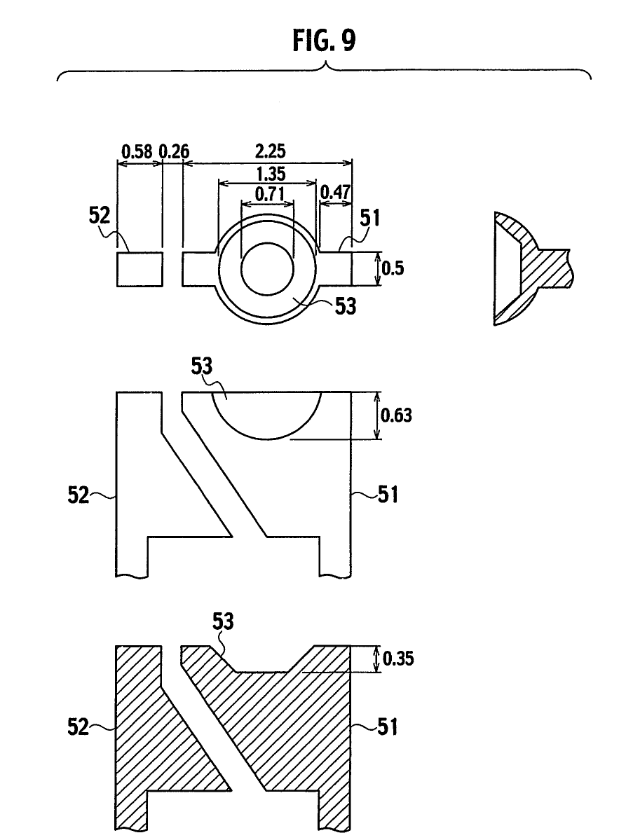

As examples of the present invention, LED devices are manufactured having the structure indicated in FIG. 9 to FIG. 11, and each of LED devices is evaluated. The refractive index n1 of the first resin layer 55, the refractive index n2 of the second resin layer 56, and the refractive index n3 of the third resin layer 57 are respectively shown in Table 1 of FIG. 7. The evaluation result is shown in Table 2 of FIG. 8.

Moreover, as Comparative example, a similar measurement is carried out on an LED device (shown for Comparative example), in which refractive indices of the respective resin layers have the relationship of n2=n3=n1, and in which an LED chip is covered with phosphors-containing resin corresponding to a second resin layer of each of the examples.

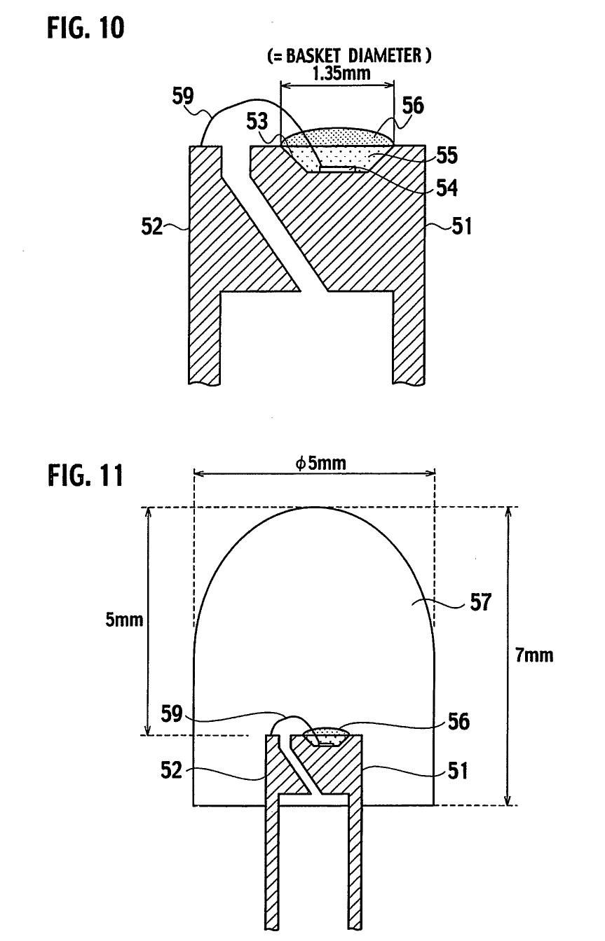

The structure of each of the LED devices and a manufacturing process thereof are as follows. A first lead frame 51 and a second lead frame 52 are shown in FIG. 9. Dimensions in FIG. 9 are shown by millimeters. As shown in FIG. 10, an ultraviolet light-emitting LED chip 54 with a size of approximately 350 μm×350 μm m square and a height of approximately 150 μm is disposed on a bowl-shaped basket 53 of the first lead frame 51, and is connected to a wire 59 by wire bonding. Next, silicon resin for a first resin layer 55 is injected into the basket 53, and the silicon resin is hardened by heating. Thereafter, in a similar way to the above, phosphors-containing resin for a second resin layer 56 made by mixing the phosphors therein is poured on the first resin layer 55, and the resin is hardened by heating. A shape of an LED portion after the first resin layer 55 and the second resin layer 56 are hardened became as shown in FIG. 10, and thicknesses of the respective resin layers above the LED chip 54 are set at approximately 0.2 mm. Thereafter, the LED portion shown in FIG. 10 is inserted into a mold in which silicon resin for a third resin layer 57 was filled. The silicon resin for the third resin layer 57 is hardened by heating, and then, is taken out from the mold. In this way, the LED devices of the examples of the present invention, which are shown in FIG. 11, are obtained. This LED device is a bullet-type LED in which a diameter is 5 mm, a height is approximately 7 mm, and a distance from the LED portion to a vertex portion is approximately 5 mm.

The silicon resin whose refractive index is different from those of the others was used as each of resin materials of the first resin layer, the second resin layer, and the third resin layer. As materials of the phosphors, phosphors emitting green light and a phosphors emitting red light, which are in the form of solid powder with a particle diameter of approximately 3 to 10 μm, are used. The phosphors respectively emitting the green light and the red light are mixed in a ratio of 2:8 into the resin of the second resin layer. A mixture ratio of the materials of the phosphors to the resin is set at 40% by weight (=weight of phosphors/weight of resin).

As the examples of the present invention, the LED device with the refractive indices having a relationship of n2>n3=n1 (shown as Structure 1 of the present invention) and the LED device with the refractive indices having a relationship of n2>n3>n1 (shown as Structure 2 of the present invention) are manufactured. Moreover, as the LED device of Comparative example, the LED device in which refractive indices of the respective resin layers having the relationship of n2=n3=n1, and in which the LED chip is covered with the phosphors-containing resin corresponding to the second resin layer of each example, is also manufactured.

Table 2 of FIG. 8 shows measured values of light output, color temperature, and chromaticity with respect to the nine LED devices. In comparison with Comparative example, in Structure 1 of the present invention, though the entire light output (integrating sphere) is substantially the same, light output in a range of excitation light (λ450 nm) is decreased, while light output in a range where the phosphors emit the light (λ450 nm) is somewhat increased. Here, the effects of “the suppression of the UV irradiation” and “the improvement of the excitation efficiency of the phosphors” appear. Moreover, in both of a color temperature and a chromaticity, light emissions in the red range (hereinafter, referred to as red light emission) are larger in Structure 1 of the present invention. The reason why is that, since the light is confined to the second resin layer containing the phosphors, green light emission excites the red phosphors. To be more precise, the light is changed from the excitation light (LED chip) to the green light emission (green phosphors), and then to the red light emission (red phosphors), and thereby increasing the red light emission. This results from the occurrence of the effect of “the improvement of the excitation efficiency of the phosphors”.

Furthermore, when comparing Structure 1 of the present invention and Structure 2 of the present invention with each other, a light output ratio of a phosphors portion to excitation light portion (=light output of the phosphors portion/light output of the excitation light portion) of Structure 1 of the present invention is approximately 1.4, while that of Structure 2 of the present invention is increased to approximately 3.0. Moreover, in both of the color temperature and the chromaticity, the red light emissions in Structure 2 are increased. This is because the difference between the refractive indices n2 and n1 is larger in Structure 2 of the present invention, and the effect of confining the light to the second resin layer is larger therein. Note that, the reason why the light output is decreased in Structure 2 of the present invention is conceived to be that, since n1 is smaller and thereby the difference in refractive index between the first resin layer and the LED chip is increased, the light extraction efficiency from the LED chip to the resin is decreased. This can be solved by enhancing the light extraction efficiency from the LED chip in such a manner that the uneven structure is formed on the surface of the LED chip and so on.

### FIFTH EMBODIMENT

A description will be made of an LED device of a fifth embodiment of the present invention, with reference to the drawings. Note that the difference between the first embodiment and the fifth embodiment will be mainly described.

Specifically, in the above-mentioned first embodiment, a refractive index n2 of the second resin layer is larger than the refractive index n1 of the first resin layer. On the contrary, in the fifth embodiment, the refractive index n2 of the second resin layer is equal to or smaller than the refractive index n1 of the first resin layer.

Configuration of LED Device

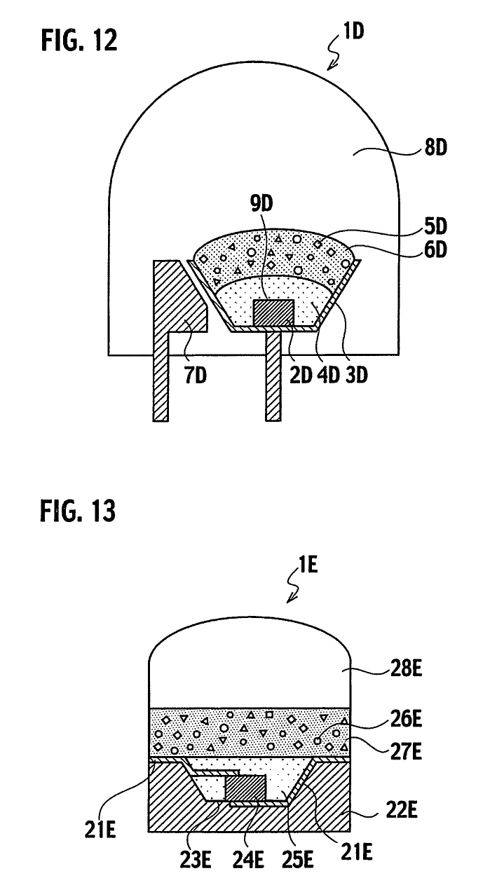

A description will be made of the LED device of the fifth embodiment of the present invention with reference to drawings. FIG. 12 shows a chip-type LED device, relating to the fifth embodiment.

As shown in FIG. 12, the chip-type LED device includes an LED chip 2D, a first lead frame 3D, a first resin layer 4D, a second resin layer 6D, a second lead frame 7D, and a third resin layer 8D. The LED device 1D is a white LED device of a bullet type, as described in the first embodiment.

The LED chip 2D emits ultraviolet light as excitation light, and includes a light emitting surface 9D which emits ultraviolet light. Further, the LED chip 2D is comprised of nitride semiconductor (e.g. includes light emitting layer on the surface of GaN substrate) and has a refractive index n0. The light emitting surface 9D having an uneven structure formed on a surface can also be used as described above.

The bowl-shaped first lead frame 3D supports the LED chip 2D.

The first resin layer 4D having a refractive index n1 is mounted on the LED chip 2D, and formed of a transparent resin. The first resin layer 4D is filled by the first lead frame 3D having the LED chip 2D, and covers the light emitting surface 9D of the LED chip 2D.

The second resin layer 6D having the refractive index n2 is mounted on the first resin layer 4D, and is formed of a transparent resin which is obtained by mixing phosphors 5. The second resin layer 6D is filled by the first lead frame 3D having the LED chip 2D and the first resin layer 4D, and covers the first resin layer 4D.

The phosphors 5d absorbs ultraviolet light (excitation light) emitted from the LED chip 2D, and emits visible light as fluorescence light. Note that, as mentioned in the first embodiment, a particle diameter for the phosphors 5d can be equal to or larger than the wavelength of the light (e.g. few micrometers), but the size of the particle diameter is not limited. The particle diameter of the phosphors 5d can be sufficiently smaller than the wavelength of the light. (e.g. 100 nm)

When the particle diameter of the phosphors 5d is equal to or larger than the wavelength of the light, the refractive index n2 of the second resin layer 6D can be regarded as the refractive index of the transparent resin forming the second resin layer 6D. On the contrary, when the particle diameter of the phosphors 5d is sufficiently smaller than the wavelength of the light, the refractive index n2 of the second resin layer 6D can be regarded as effective refractive index upon consideration of the phosphors 5d.

The second lead frame 7D is adjacent to the first lead frame 3D.

The third resin layer 8D having the refractive index n3 is mounted on the second resin layer 6D, and covers the LED chip 2D, the first resin layer 4D, the second resin layer 6D, the first lead frame 3D and the second lead frame 7D.

Hereafter, the relationships among the refractive index n0 of the LED chip 2D, the refractive index n1 of the first resin layer 4D, the refractive index n2 of the second resin layer 6D, and the refractive index n3 of the third resin layer 8D, will be described. The refractive index n2 of the second resin layer 6D is larger than the refractive index n3 of the third resin layer 8D. The refractive index n1 of the first resin layer 4D is equal to or larger than the refractive index n2 of the second resin layer 6D.

As mentioned above, when the particle diameter of the phosphors 5d is sufficiently smaller than the wavelength of the light, the refractive index n2 of the second resin layer 6D can be regarded as effective refractive index upon consideration of the phosphors 5d. In that case, the refractive index of the transparent resin forming the second resin layer 6D can be smaller than the refractive index n3 of the third resin layer 8D, if the effective refractive index upon consideration of the phosphors 5d is larger than the refractive index n3 of the third resin layer 8D.

Further, since the LED chip 2D is generally formed of nitride semiconductor, the refractive index n0 of the LED chip 2D is larger compared to the refractive index n1 of the first resin layer 4D, the refractive index n2 of the second resin layer 6D, and the refractive index of the third resin layer 3d.

Note that the manufacturing method for the chip-type LED device is omitted since the manufacturing method for the chip-type LED device relating to the fifth embodiment of the present invention is no different than the manufacturing method described in the first embodiment.

Functions and Effects

According to the chip-type LED device 1D of the fifth embodiment of the present invention, the refractive index n1 of the first resin layer 4D is equal to or larger than the refractive index n2 of the second resin layer 6D. Therefore, the excitation light reaching at the second resin layer 6D possibly decreases in the consequence that the LED chip 2D is totally reflected on the boundary surface between the first resin layer 4D and the second resin layer 6D, compared to the case where the refractive index n2 of the second resin layer 6D is larger than the refractive index n1 of the first resin layer 4D. Further, the effect of confining the ultraviolet light to the second resin layer 6 possibly decreases in the consequence that the excitation light can be hardly totally reflected on the boundary surface between the first resin layer 4D and the second resin layer 6D when it is totally reflected on the boundary surface between the second resin layer 6D and the third resin layer 8D.

On the contrary, generally the refractive index n0 of the LED chip 2D is larger than the refractive index n1, which is formed of transparent resin. Further, as the difference between the refractive index n0 of the LED chip 2D and the refractive index n1 of the first resin layer 4D becomes bigger, the extraction efficiency of the excitation light emitted from the LED chip 2D becomes smaller. Therefore, as described in the fifth embodiment of the present invention, the difference between the refractive index n0 of the LED chip 2D and the refractive index n1 of the first resin layer 4D can be reduced in the case where the refractive index n1 of the first resin layer 4D is equal to or smaller than the refractive index n2 of the second resin layer 6D. Thus, the extraction efficiency of the excitation light emitted from the LED chip 2D is improved.

Hence, brightness enhancement (improvement on light emitting efficiency) of the chip-type LED device is realized as a whole, in the case where the increased brightness resulted from the improvement on extraction efficiency of the excitation light, is larger than the decreased brightness resulted from the decrease in the excitation light reaching at the second resin layer 6D as well as the decrease in the effect of the confining the excitation light.

Further, as mentioned in the first embodiment, according to the chip-type LED device 1D of the fifth embodiment of the present invention, excitation light emitted from the LED chip 2D is totally reflected on the boundary surface between the second resin layer 6D and the third resin layer 8D. Thus, the totally reflected excitation light returns to the second resin layer 6D, and the excitation efficiency is improved.

Moreover, as mentioned in the first embodiment, according to the chip-type LED device 1D of the fifth embodiment of the present invention, the first resin layer 4D is placed between the second resin layer 6D, which includes the phosphors 5d, and the LED chip 2D. This configuration suppresses the LED chip 2D from being affected by the heat caused by the phosphors 5d when excitation light is emitted.

### SIXTH EMBODIMENT

A description will be made of an LED device of a sixth embodiment of the present invention, with reference to the drawings. Note that the difference between the fourth embodiment and the sixth embodiment will be mainly described.

Specifically, in the above-mentioned fourth embodiment, a resin layer including phosphors is hardened after a resin including the phosphors is filled.

On the contrary, in the sixth embodiment, a resin layer including phosphors is formed of a material where a resin including phosphors processed into sheet shape.

Configuration of LED Device

A description will be made of the LED device of the sixth embodiment of the present invention with reference to drawings. FIG. 13 shows a chip-type LED device, relating to the sixth embodiment.

As shown in FIG. 13, the chip-type LED device 1E includes metal lead wires 21E, an insulating substrate 22E, an LED chip 24E, a first resin layer 25E, a phosphor sheet 27E, a third resin layer 28E.

The metal lead wires 21E is connected to an upper surface and a lower surface of the LED chip 24E and supply current to the LED chip 24E.

The insulating substrate 22E is formed of an insulating material and has a recess 23E where the LED chip 24E is arranged.

The LED chip 24E emits ultraviolet light as excitation light. The LED chip 24E is arranged on the recess 23E of the insulating substrate 22E.

The first resin layer 25E having a refractive index n1 (for example 1.42) is mounted on the LED chip 24E, and formed of a transparent resin. The first resin layer 25E is filled by the recess 23E of the insulating substrate 22E.

The phosphor sheet 27E is a sheet layer (second resin layer) having the refractive index n2 (for example 1.56), and is mounted on the first resin layer 25E and the insulating substrate 22E. The phosphor sheet 27E is formed of a transparent resin which is obtained by mixing phosphors 26E. The phosphor sheet 27E pasted on the insulating substrate 22E where the first resin layer 25E is filled by the recess 23E.

The phosphors 26E absorbs ultraviolet light (excitation light) emitted from the LED chip 24E, and emits visible light as fluorescence light. Note that, as mentioned in the first embodiment, a particle diameter for the phosphors 26E can be equal to or larger than the wavelength of the light (e.g. few micrometers), but the size of the particle diameter is not limited. The particle diameter of the phosphors 26E can be sufficiently smaller than the wavelength of the light. (e.g. 100 nm)

When the particle diameter of the phosphors 26E is equal to or larger than the wavelength of the light, the refractive index n2 of the phosphor sheet 27E can be regarded as the refractive index of the transparent resin forming the phosphor sheet 27E. On the contrary, when the particle diameter of the phosphors 26E is sufficiently smaller than the wavelength of the light, the refractive index n2 of the phosphor sheet 27E can be regarded as effective refractive index upon consideration of the phosphors 26E.

The third resin layer 28E having the refractive index n3 (for example 1.52) is mounted on the phosphor sheet 27E.

Functions and Effects

According to the chip-type LED device 1E of the sixth embodiment of the present invention, a resin layer (second resin layer) including phosphors is formed of the phosphor sheet 27E. Accordingly, the chip-type LED device 1E can be manufactured by pasting the phosphor sheet 27E on the insulating substrate 22E where the first resin layer 25E is filled by the recess 23E. That is, the chip-type LED device 1E can be easily manufactured without filling and hardening a resin including phosphors.

### EXAMPLE 2

As an example of the present invention, a description will be made of the second embodiment with reference to the drawings. Note that, in the second embodiment, a measurement is carried out on the light emitting efficiency of the chip-type LED device, as well as the excitation efficiency of phosphors included in the chip-type LED device.

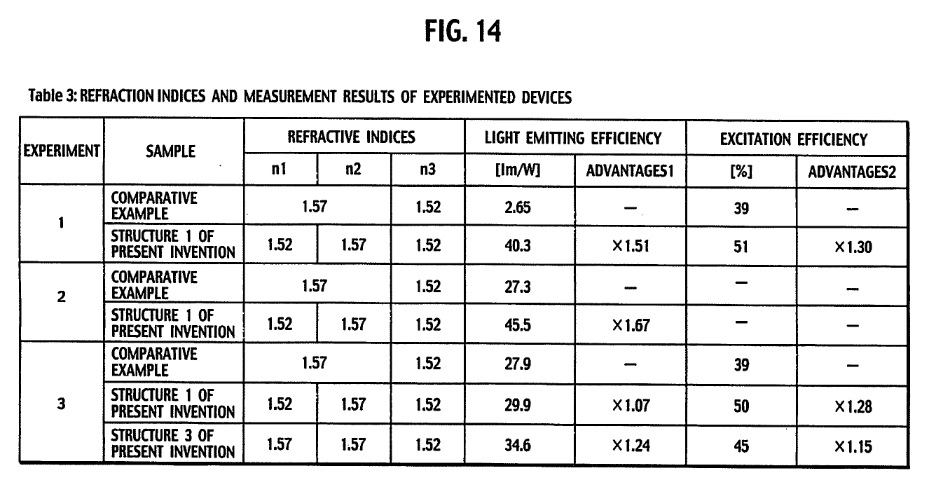

Specifically, the LED device (Structure 1) having similar structure shown in FIG. 2 and the LED device (Structure 3) having similar structure shown in FIG. 12 is manufactured. That is, in the LED device of the Structure 3, the refractive index n1 of the first resin layer, the refractive index n2 of the second resin layer, and the refractive index n3 of the third resin layer have a relationship of n1=n2>n3. The refractive indices of each resin layer are respectively shown in Table 3 of FIG. 14.

LED devices for comparison having structure where the second resin layer including the phosphors directly covers the LED chip 2 in the LED device shown in FIG. 2, are prepared (shown for Comparative example in Table 3).

The measurement results of each LED devices are shown in Table 3 of FIG. 14. As shown in Table 3 of FIG. 14, Structure 1 and Structure 3 shows superior result compared to Comparative examples in both the light emitting efficiency and the excitation efficiency for each experiment (experiment 1-3). This is due to the first resin layer prevents the LED chip from being affected by the heat caused by the phosphors.

As shown in the result of the experiment 3, Structure 3 shows superior result compared to Structure 1 in the light emitting efficiency, Structure 1 shows superior result compared to Structure 3 in the excitation efficiency of phosphors.

Here, since the refractive index n2 of the second resin layer 6 is larger than the refractive index n1 of the first resin layer 4 in Structure 1, the ultraviolet light is confined into the second resin layer 6 strongly. Thereby, it is considered that the phosphors included in the second resin layer 6 are easily excited, and the excitation efficiency of phosphors is improved.

On the other hand, since the refractive index n2 of the second resin layer 6D is equal to the refractive index n1 of the first resin layer 4D, the difference of the refractive index between the LED chip 2D and the first resin layer 4D is smaller compared to Structure 1. Thereby, it is considered that the emitting efficiency is improved because the light can be easily extracted from the LED chip 2D to the first resin layer 4D.

### OTHER EMBODIMENTS

Although the description was made with reference to the above-mentioned embodiments, the description and the drawings should not be regarded as limiting the invention. For the persons skilled in the art, various embodiments, examples and techniques would be obtained through the description of the present invention.

For example, in the first to fourth embodiments, the description is made that a particle diameter for the phosphors is equal to or larger than the wavelength of the light (e.g. few micrometers), but the size of the particle diameter is not limited. To be specific, the particle diameter of the phosphors can be sufficiently smaller than the wavelength of the light. (e.g. 100 nm)

When the particle diameter of the phosphors is equal to or larger than the wavelength of the light, the refractive index n2 of the second resin layer 6 can be regarded as the refractive index of the transparent resin forming the second resin layer 6. On the contrary, when the particle diameter of the phosphors is sufficiently smaller than the wavelength of the light, the refractive index n2 of the second resin layer 6 can be regarded as effective refractive index upon consideration of the phosphors 5d.

Additionally, although the first resin layer 4 is not preferred to include the phosphors, little amount of phosphors can be surely included insofar as it does not affect the LED chip 2. Further, the third resin layer 8 can surely include phosphors insofar as it does not prevent the emission of the fluorescence light from the phosphors included in the second resin layer 6. In that case, the phosphors included in the third resin layer 8 can be excited by the fluorescence light emitted from the phosphors included in the second resin layer 6. For example, the second resin layer 6 can include the phosphors emitting blue light by absorbing the ultraviolet light emitted from the LED chip 2. In the same way, the third resin layer 8 can include the phosphors emitting red light and green light by absorbing the blue light emitted from the phosphors included in the second resin layer 6.

What is claimed is:

1. An LED device, comprising:
an LED chip, a first layer provided on the LED chip, a second layer provided on the first layer, and a third layer provided on the second layer, wherein,
the first layer has a refractive index n1,
the second layer has a refractive index n2, and includes phosphors emitting fluorescence light by absorption of excitation light emitted from the LED chip,
the third layer has a refractive index n3,
the refractive index n2 is larger than the refractive index n3.

2. The LED device according to claim 1,
wherein, the refractive index n2 is larger than the refractive index n1.

3. The LED device according to claim 1,
wherein, the refractive index n1 is equal to the refractive index n2.

4. The LED device according to claim 1,
wherein, the refractive index n1 is larger than the refractive index n2.

5. The LED device according to claim 1,
wherein, the refractive index n3 is larger than the refractive index n1.

6. The LED device according to claim 1, wherein,
the LED chip emits an ultraviolet light as the excitation light,
the phosphors emit a visible light as the fluorescence light.

7. The LED device according to claim 1, wherein,
the second layer is composed of a phosphor sheet.

8. The LED device according to claim 1, wherein,
the LED chip has a light emitting surface which emits the excitation light,
the light emitting surface includes an uneven surface having small scaled convex portion or concave portion.

9. The LED device according to claim 1, wherein,
the first layer and the second layer are formed of resins.

10. The LED device according to claim 1, wherein,
the third layer is formed of a resin.

11. The LED device according to claim 1, wherein,
the third layer is formed of a glass.
